(19) United States
(12) Patent Application Publication
(10) Pub. No.: US 2008/0315917 A1
(43) Pub. Date: Dec. 25, 2008

(54) Programmable computing array

(75) Inventors: Leonard Forbes, Corvallis, OR (US); Hussein J. Hanafi, Basking Ridge, NJ (US); Alan R. Reinberg, Plano, TX (US)

Correspondence Address: BROOKS, CAMERON & HUEBSCH , PLLC, 1221 NICOLLET AVENUE, SUITE 500, MINNEAPOLIS, MN, 55403, US

(73) Assignee: Micron Technology, Inc.

(21) Appl. No.: 11/821,011

(22) Filed: Jun. 21, 2007

(51) Int. Cl. H03K 19/177

(52) U.S. Cl. 326/41

(57) ABSTRACT

Methods, devices, and systems for programmable computing arrays have been described. One or more embodiments include programming both a first and a second floating gate of a combined memory and logic element to one of at least two states, wherein programming the floating gates to one of the at least two states causes the combined memory and logic element to operate as a first logic gate type. One or more embodiments also include programming both the first and the second floating gates of the combined memory and logic element to another of the at least two states, wherein programming the floating gates to another of the at least two states causes the combined memory and logic element to operate as a second logic gate type, the second logic gate type being different from the first logic gate type.

### TECHNICAL FIELD

The present disclosure relates generally to programmable computing arrays and, more particularly, to dual floating gate transistors as logic gates in programmable computing arrays.

### BACKGROUND

Communication bottlenecks between memory and logic modules are one of the most serious problems in recent deep submicron very-large-scale integration (VLSI) systems. However, the programmable computing array is more complex to build and has lower storage density than a normal memory array because of the overhead involved in the storage and logic elements and the difficulty in producing cells with both the storage and logic elements. One example of a programmable logic arrays using floating gates is provided in commonly assigned U.S. Pat. No. 6,124,729, entitled, “Field Programmable Logic Arrays with vertical transistors, issued Sep. 26, 2000, and having at least one common inventor. The cells described therein have a semiconductor pillar providing a shared source and drain region for two separate transistors each having individual floating gates and control lines. Whole arrays of such structures are field programmed together, versus programming on an individual cell basis, in order to function as a particular type of logic plane. In this previous approach, however, the number of connects between planes due to the absence of programmability of each cell independently and need to connect various entire planes in a certain way to achieve a desired logic state may add to the complexity and area consumed by such a layout.

### BRIEF DESCRIPTION OF THE DRAWINGS

FIG. 1A illustrates an embodiment of a memory in logic element, e.g., cell, that can be programmed and operated as part of a programmable computing array.

FIG. 1B is an energy band diagram which illustrates one programmed embodiment of the memory in logic cell shown in FIG. 1 when both a first and a second floating gates, representing a first input to the memory in logic cell, are uncharged.

FIG. 1C is an energy band diagram which illustrates another programmed embodiment of the memory in logic cell when both the first and the second floating gates, representing a first logical input to the memory in logic cell are charged negative.

FIG. 2 illustrates an embodiment for the random logic utilization of a memory in logic cell that can be programmed and operated as part of a programmable computing array.

FIG. 3A illustrates a programmable computing array implementing embodiments of the memory in logic cells described in connection with FIGS. 1A-2.

FIG. 3B illustrates a truth table for various first, second, and third logical inputs to the programmable computing array shown in FIG. 3A

FIG. 3C illustrates a truth table for various first, second, and third logical inputs to the programmable computing array shown in FIG. 3A when the outputs of the memory in logic cells are inverted.

FIG. 4 illustrates a programmable computing array implementing embodiments of the memory in logic cells described in connection with FIGS. 1A-3C.

FIG. 5 illustrates an embodiment of a memory-in-logic computing system where multiple programmable computing arrays, such as shown in FIG. 4, are coupled together via a programmable routing structure.

### DETAILED DESCRIPTION

Methods, devices, and systems for programmable computing arrays have been described. One or more embodiments include programming both a first and a second floating gate of a combined memory and logic element to one of at least two states, wherein programming the floating gates to one of the at least two states causes the combined memory and logic element to operate as a first logic gate type. One or more embodiments also include programming both the first and the second floating gates of the combined memory and logic element to another of the at least two states, wherein programming the floating gates to another of the at least two states causes the combined memory and logic element to operate as a second logic gate type, the second logic gate type being different from the first logic gate type.

According to one or more embodiments, the first and the second floating gates are either charged or discharged together and used as a first input to the memory in logic cell. A first control gate associated with the first floating gate is used as a second input to the memory in logic cell. A second control gate associated with the second floating gate is used as a third input to the memory in logic cell. When the first and the second floating gates (first inputs) to the memory in logic cell are charged the memory in logic cell performs a first logical operation based on the second and the third logical inputs provided to the first and the second control gates. When the first and the second floating gates (first inputs) to the memory in logic cell are uncharged the memory in logic cell performs a second logical operation based on the second and the third logical inputs provided to the first and the second control gates. The output of a memory in logic cell can be inverted to perform a third and a fourth logical operation.

In one or more embodiments, the memory in logic cell is configured as a lightly doped, narrow vertical semiconductor pillar having symmetrical floating gates and control gates formed on opposing sides of the pillar such that a voltage threshold (Vt) on one side of the pillar depends on a charge and potential applied to a floating gate and a control gate, respectively, on the opposite side of the pillar. In this manner, the Vts on opposing sides of the pillar are not independent as they would be for two separate transistors. The memory in logic cell is formed symmetrically and both floating gates are either charged or uncharged, i.e., both have the same charge state.

A memory-in-logic structure, according to embodiments described herein, in which storage functions are distributed over a logic-circuit plane to achieve programmable computing, can reduce the bottleneck between memory and logic modules. The memory-in-logic structure allows each individual cell in an array to be programmed to a desired mode, thus allowing for greater flexibility in configuring an array of cells to a particular desired state. A memory-in-logic structure provides for a simplified circuit design due to the flexibility associated with each cell being individually programmable. Also, there should be an increase in reliability associated with these structures because of the decrease in the number of connects between cells due to the programmability of each cell and the lack of the need to connect certain cells in a certain way to achieve a desired logic state. When a storage function is included in each cell of a programmable computing array, the array may be regarded as a logic array whose elementary gates and connections can be programmed to realize a desired logical behavior.

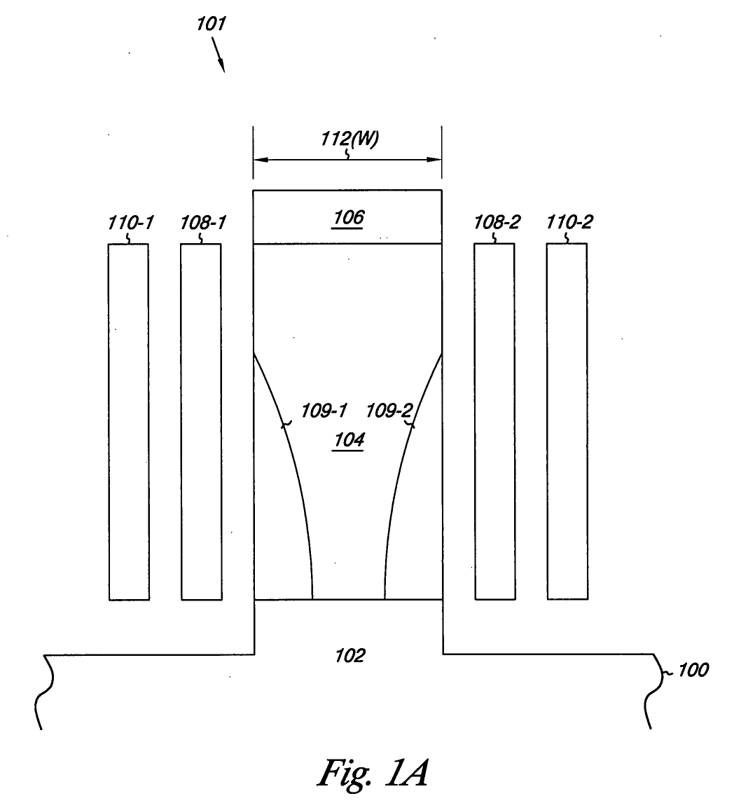

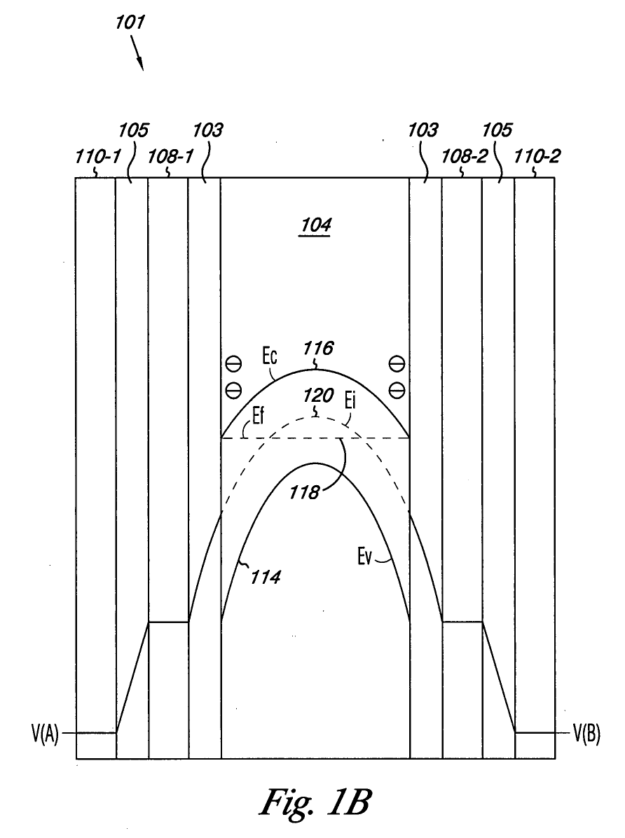

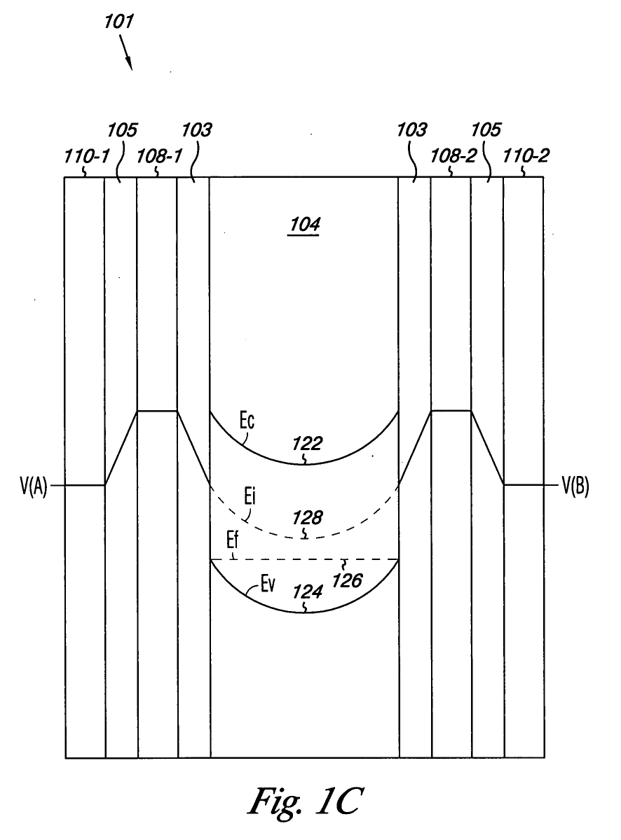

FIG. 1A illustrates an embodiment of a memory in logic element 101, e.g., cell, that can be programmed and operated as part of a programmable computing array. As shown in the embodiment of FIG. 1A the cell 101 is formed on a substrate 100 and includes transistor structure having dual floating gates. That is, the cell 101 includes a first source/drain region 102, e.g., source, and a second source/drain region 106, e.g., drain, separated by a body region 104. As shown in the example embodiment of FIG. 1A the cell 101 can be formed “vertically” on the substrate 100 such that the body region 104 is formed as a “vertical” pillar extending from the source 102 to the drain 106.

As shown in FIG. 1A, the cell 101 includes a first 108-1 and a second floating gate 108-2 formed on opposing sides of the body region 104. A first and a second control gate, 110-1 and 110-2 respectively, are shown opposing the first 108-1 and the second 108-2 floating gates. One example of a method for forming a vertical transistor structure of cell 101 is provided in commonly assigned U.S. Pat. No. 6,208,164, entitled, “Programmable Logic Array with Vertical Transistors”, issued Mar. 27, 2001 and having common inventorship. Another is provided in commonly assigned U.S. Pat. No. 6,486,703, entitled, “Programmable Logic Array with Vertical Transistors”, issued Nov. 26, 2002 and having common inventorship. The same are incorporated herein by reference.

In contrast to this earlier work, however, the vertical pillar forming the body region 104 has a width (W) 112 which is thin, e.g., less than 100 nm, and a doping concentration which is sufficiently low, e.g., less than 1017/cm³, so that a threshold voltage (Vt) on one side of body region 104 depends on a charge on the floating gate and a potential applied to the control gate on the other side. That is, a first threshold voltage (Vt1) necessary to create a first channel 109-1 between the source region 102 and the drain region 106 on the side of the body region 104 opposing the first floating gate 108-1 is dependent on the charge on the second floating gate 108-2 and the potential applied to the second control gate 110-2 on the side of the body region 104 opposing the second floating gate 108-2. Similarly, a second threshold voltage (Vt2) necessary to create a second channel 109-2 between the source region 102 and the drain region 106 on the side of the body region 104 opposing the second floating gate 108-2 is dependent on a charge on the first floating gate 108-1 and the potential applied to the first control gate 110-1 on the side of the body region 104 opposing the first floating gate 108-1.

Hence, in contrast to the above earlier work, the respective threshold voltages, e.g., Vt1 and Vt2, and the first and the second floating gates, 108-1 and 108-2, of the cell 101 are not independent as they would be for two separate transistors as described in the above mentioned work by the same inventors. Also, according to one or more embodiments disclosed herein, both the first and the second floating gates, 108-1 and 108-2, are either charged or not charged. That is, both the first and the second floating gates, 108-1 and 108-2, are expressly programmed and the cell 101 operated such that the first and the second floating gates, 108-1 and 108-2, have a same charge state.

As described in more detail below, the first 108-1 and the second floating gate 108-2 serve as a first logical input to the cell 101. The first control gate, e.g., 110-1 serves as a second logical input to the cell 101. The second control gate, e.g., 110-2, serves as a third logical input to the cell 101. In the embodiments, the cell 101 is programmed such that the cell 101 performs a first logical operation when the first and the second floating gates, 108-1 and 108-2, are in a first state, e.g., charged, and performs a second logical operation when the first and the second floating gates, 108-1 and 108-2, are in a second state, e.g., uncharged.

In the example embodiment described in FIG. 1A, dual floating gate transistor structure is symmetrical. In this embodiment the dual floating gate transistor structure to the cell 101 includes two vertical floating gates, 108-1 and 108-2. In this embodiment, the dual floating gate transistor structure to the cell 101 includes two vertical control gates, 110-1 and 110-2. As mentioned above, the charge on the floating gates, 108-1 and 108-2, and the potential applied to the control gates, 110-1 and 110-2, determine the threshold voltage to turn the transistor on and allow electron flow from the source 102 to the drain 106 through the body region 104. The threshold voltage, 109-1, 109-2, for the transistor structure on one side of the body region 104 depends on the charge on the floating gate, 108-1 and 108-2, and control gate, 110-1 and 110-2, input signal, e.g., potential applied to control gates, 110-1 and 110-2, as a second and third logical input to the cell 101, respectively.

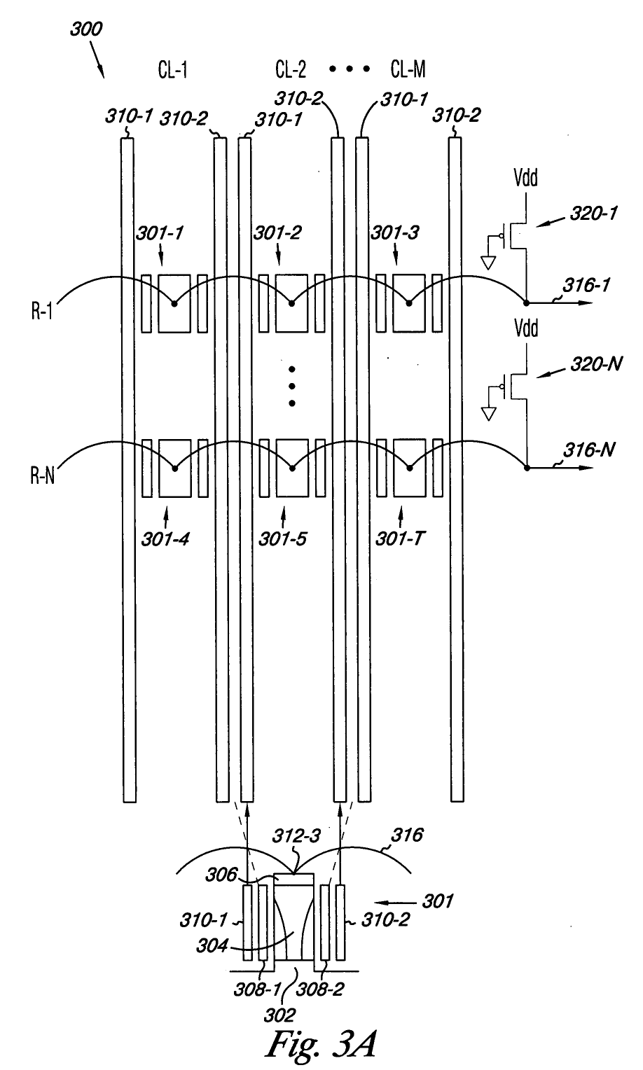

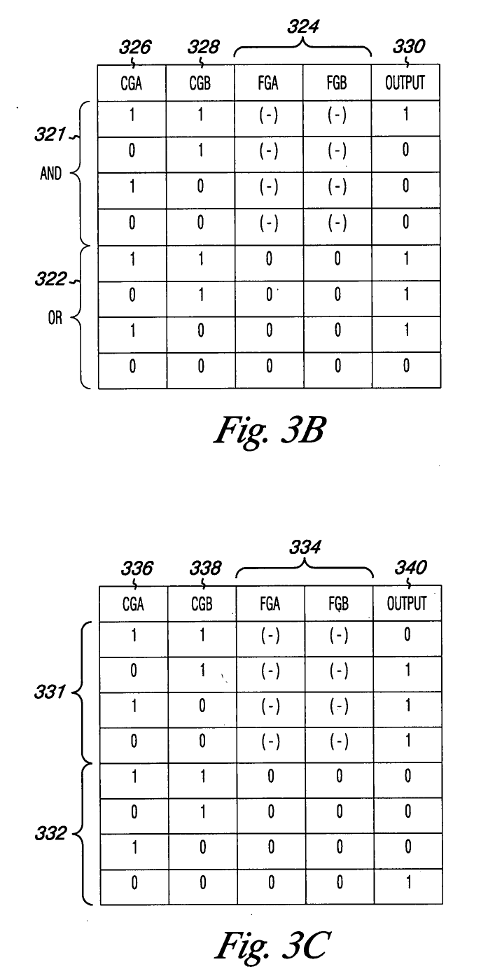

According to embodiments, which will be described in more detail below in connection with the truth tables shown in FIGS. 3B-3C, if both floating gates, 108-1 and 108-2, are charged negative the transistor structure of the cell 101, can only be turned on if both control gates, 110-1 and 110-2, e.g., second and third logical inputs, have a positive potential applied thereto, e.g., a positive second and third input signals above Vt1 and Vt2. Alternatively, if both floating gates, 108-1 and 108-2, are uncharged, either control gate, 110-1 or 110-2, going positive, e.g., either a positive second input on first control gate 110-1 and/or a positive third input on second control gate 110-2, can turn the transistor on. Again, as described above, both floating gates are either charged or uncharged at any given time, i.e., they both have the same charge state. One of ordinary skill in the art will appreciate the manner in which the first and the second floating gates, 108-1 and 108-2, can be charged and charge removed therefrom, e.g., either through hot electron injection, Fowler Nordheim tunneling, etc. Likewise, one of ordinary skill in the art will appreciate the manner in which exceeding a first and second threshold voltage, e.g., Vt1 and Vt2, can create inversion layers in the body region 104 sufficient to a form the first and/or second conductive channels, e.g., 109-1 and 109-2, sufficient to permit conduction between the source 102 and drain 106 regions.

The technique described herein for using the charge on one floating gate, e.g., the first floating gate, 108-1, on one side of the body region 104, e.g., side opposing floating gate 108-1, to control the threshold voltages, Vt2, on the other side, e.g., side opposing floating gate 108-2, has previously been described only in an asymmetrical fashion in previous work by inventors common to the present disclosure for purposes of signal processing and as mixer circuits. For example, one description of asymmetrically using the charge on one floating gate, e.g., the charge on the first floating gate, 108-1, on one side of the body region 104, e.g., side opposing floating gate 108-1, to control the threshold voltages, Vt2, on the other side, e.g., side opposing floating gate 108-2, is described in commonly assigned U.S. Pat. No. 6,104,068, entitled, “Structure and Method for Improved Signal Processing”, issued Aug. 15, 2000, and having common inventorship. In contrast to this previous work, however, the cell 101 is symmetrical and the first and the second floating gates, 108-1 and 108-2, are purposefully programmed to have a same state, e.g. charged or uncharged.

As described in more detail below in connection with the truth tables of FIGS. 3B-3C, if both floating gates, 108-1 and 108-2, are not charged, the threshold voltages, Vt1 and Vt2, necessary to form channels, 109-1 and 109-2, will both be lower and will have approximately the same value. If, as illustrated further in connection with the truth tables of FIGS. 3B-3C, both a potential applied to the second input, e.g., control gate 110-1, and potential applied to the third input, e.g., control gate 110-2, are low, then a low logical output will be produced. However, when the first and the second floating gates, 108-1 and 108-2, are in this uncharged state, a high potential applied to either the second input, e.g., control gate 110-1, or the third input, e.g., control gate 110-2, will be sufficient to individually turn the transistor structure of cell 101 “ON” producing conduction between the source 102 and the drain 106 such that a high logical output will be produced. As the reader will appreciate, when the first and the second floating gates, 108-1 and 108-2, are in this uncharged state, a high potential applied to both the second input, e.g., control gate 110-1, and the third input, e.g., control gate 110-2, will turn the transistor structure of cell 101 “ON” producing conduction between the source 102 and the drain 106 such that a high logical output will be produced, e.g., an OR logical operation performed.

Alternatively, as described in more detail below in connection with the truth tables of FIGS. 3B-3C, if both floating gates, 108-1 and 108-2, are charged, i.e., charged negative, the threshold voltages, Vt1 and Vt2, necessary to form channels, 109-1 and 109-2, will both be higher and will have approximately the same value. If, as illustrated further in connection with the truth tables of FIGS. 3B-3C, both a potential applied to the second input, e.g., control gate 110-1, and potential applied to the third input, e.g., control gate 110-2, are low, then a low logical output will be produced, e.g., the cell will not turn “ON”. That is, the potential applied to the second and/or third input, e.g., control gates 110-1 and 110-2, will not be sufficient to overcome the threshold voltages, Vt1 and Vt2, and create channels, 109-1 and 109-2, to produce conduction between source region 102 and drain region 106. According to embodiments, either high input alone to the second or third input, e.g., control gate 110-1 or 110-2, will not by itself be sufficient to overcome, Vt1 and Vt2, sufficient to turn on the transistor structure of cell 101. The charge states of the first and the second floating gates, 108-1 and 108-2, and the potentials applied to the first and the second control gates, 110-1 and 110-2, will control the threshold voltages, e.g., Vt1 and Vt2, on each side of the body region 104 necessary to create the respective channels, 109-1 and 109-2.

Hence, if both the first and the second floating gates are charged negative, e.g., a second programmed state, then an input to only one of the first or the second control gates, e.g., second and third inputs, is insufficient to individually turn the transistor structure of cell 101 “ON” and produce conduction between the source 102 and the drain 106 such that a low logical output will be produced. Alternatively, when both the first and the second floating gates are charged negative, e.g., a second programmed state, then only a positive input signal applied to both the first and the second control gates, 110-1 and 110-2, e.g., second and third inputs, will be sufficient to turn the transistor structure of cell 101 “ON” and produce conduction between the source 102 and the drain 106 such that a high logical output will be produced. e.g., a logical AND operation. That is, the transistor structure of cell 101 will only conduction when both inputs, e.g., control gates 110-1 and 110-2 are both high.

Again, as noted above, the charge states, e.g., either charged or not charged, and the potentials applied to the second and the third input, 110-1 and 110-2, e.g., on one side of the body region 104 will control the Vt1 and Vt2, of the other side such that the transistor structure of cell 101 will turn “ON” in the charged state if and only if both the second and the third input, e.g., control gate 110-1 and 110-2, are at a positive or high logic level. As described next in connection with FIGS. 1B and 1C, the threshold voltages, can be determined by appropriate doping and thickness, e.g. width (W) 112 of the body region 104, e.g., vertical pillar, gate insulator thickness, work functions of the gate materials, and voltages of the logic levels, e.g., charge on the first logic input (floating gates 108-1 and 108-2, potential applied to the second logic input (control gate 110-1), and potential applied to the third logic input (control gate 110-2).

FIG. 1B is an energy band diagram which illustrates one, e.g., a “first”, programmed embodiment of the memory in logic cell 101 when both the first and the second floating gates, 108-1 and 108-2, representing a first input to the memory in logic cell 101, are uncharged. The embodiment of FIG. 1B illustrates the body region 104 as a vertical pillar. A first gate dielectric 103, e.g., gate oxide, is provided on both sides of the body region 104 and separates the body region 104 from the first floating gate 108-1 and the second floating gate 108-2, respectively, which are symmetrically formed on opposite sides of the body region 104. As shown in FIG. 1B the first control gate 110-1 opposes the first floating gate 108-1 and the second control gate 110-2 opposes the second floating gate 108-2 as separated by a second gate dielectric 105, e.g., gate oxide, respectively. FIG. 1B illustrates generally the relative valence (Ev) 114, conduction (Ec) 116, intrinsic (Ei) 120, and Fermi (E_{F}) 118 energy band levels of the memory in logic cell 101, when the first and the second floating gates, 108-1 and 108-2, are uncharged.

As shown in the embodiment of FIG. 1B, when the first and the second floating gates, 108-1 and 108-2, are uncharged the energy of the conduction band (Ec) 116 is above the Fermi energy (E_{F}) 118 level and the valence energy (Ev) 114 level of the body region 104 such that either a positive potential, V(A) or V(B) provided to the first or the second control gates, 110-1 and 110-2, e.g., representing a second and/or third input to the memory in logic cell 101, will be sufficient to create an inversion layer in the body region 104 and form a conduction channel, e.g., as shown the Fermi level (E_{F}) 118 in the body region 104 is above the intrinsic energy level (Ei) 120. As the reader will appreciate the “work function” is the amount of work (in electron-volts) required to overcome the inherent barrier to the flow of electrons in a given material. The work function can be used to gauge the resistance of a particular material to the flow of current.

Hence, according to this example programmed embodiment the potential distribution to the transistor structure of the memory in logic cell when both floating gates are uncharged is high and either of the control gates, 110-1 and 110-2, can turn the transistor structure of the memory in logic cell 101 “ON”. When either the first and/or second control gates, 110-1 and 110-2, receive a positive input, the potential distribution in the programmed embodiment of FIG. 1B produces electrons in the inversion layer and channel for the transistor structure of the memory in logic cell 101, thus allowing electron flow from the source 102 to the drain 106.

As illustrated in the truth tables shown in FIGS. 3B-3C, when the first and the second floating gates, 108-1 and 108-2, e.g., first logical inputs, of the memory in logic cell 101 are programmed to this state, the potential distribution of the memory in logic cell 101 causes the cell to perform as a OR logic gate for second and third input signals applied to the first and the second control gates, 110-1 and 110-2, respectively. That is, as shown in FIGS. 3B-3C, the memory in logic cell, programmed to this state will output a logic value of 1 when either one or both of the control gates, 110-1 and 110-2, have a positive input, e.g., logic value “1”, applied thereto.

FIG. 1C is an energy band diagram which illustrates another, e.g., a “second”, programmed embodiment of the memory in logic cell 101 when both the first and the second floating gates, 108-1 and 108-2, representing a first logical input to the memory in logic cell 101, are charged negative. The embodiment of FIG. 1C again illustrates the body region 104 as a vertical pillar. A first gate dielectric 103, e.g., gate oxide, is provided on both sides of the body region 104 separating the body region 104 from the first floating gate 108-1 and the second floating gate 108-2, respectively, which are symmetrically formed on opposite sides of the body region 104. As shown in FIG. 1C a first control gate 110-1, e.g., second logical input, opposes the first floating gate 108-1 and a second control gate 110-2, e.g., third logical input, opposes the second floating gate 108-2 as separated by a second gate dielectric 105, e.g., gate oxide, respectively. FIG. 1C illustrates generally the relative valence (Ev) 124, conduction (Ec) 122, intrinsic (Ei) 128, and Fermi (E_{F}) 126 energy band levels of the memory in logic cell 101, when the first and the second floating gates, 108-1 and 108-2, are charged, e.g., in a second programmed state.

As shown in the embodiment of FIG. 1C, when the first and the second floating gates, 108-1 and 108-2, are charged the energy of the Fermi energy (E_{F}) 126 level is entirely below the intrinsic energy (Ei) 128 level of the body region 104 and much closer to the valence energy (Ev) 124 level. As such, if both the second and the third logical inputs, e.g., V(A) and V(B), provided to the first and the second control gates, 110-1 and 110-2, are low then the threshold voltages (Vt) necessary to create a channel in either side of the body region 104 will be the same or higher and no conduction will occur. Additionally, in this programmed embodiment, applying a positive potential to either logical input, e.g., second logical input V(A) and third logical input V(B), will not by itself be sufficient to exceed the threshold voltages necessary to create a channel in either side of the body region 104 and cause conduction to occur. Again, according to embodiments the charge states on the floating gates, e.g., first inputs 108-1 and 108-2, and the potentials applied to the first and/or second control gates, e.g., second and third inputs 110-1 and 110-2, on one side of the body region 104 control the threshold voltage on the other side.

Hence, as the reader will appreciate according to this programmed embodiment, exceeding the threshold voltages, Vt1 and Vt2, sufficient enough to create a channel in order for the body region to conduct a current, e.g., turn “ON”requires that a positive potential, V(A) and V(B), be applied to both the first and the second control gates, 110-1 and 110-2, in order to create an inversion layer in the body region 104 and form a conduction channel.

As illustrated in the truth tables shown in FIGS. 3B-3C, when the first and the second floating gates, 108-1 and 108-2, e.g., first logical inputs, of the memory in logic cell 101 are programmed to this state, the potential distribution of the memory in logic cell 101 causes the cell to perform as an AND logic gate for second and third input signals applied to the first and the second control gates, 110-1 and 110-2, respectively. That is, as shown in FIGS. 3B-3C, the memory in logic cell 101, programmed to this state will output a logic value of 1 only when both of the control gates, 110-1 and 110-2, have a positive input, e.g., logic value “1”, applied thereto.

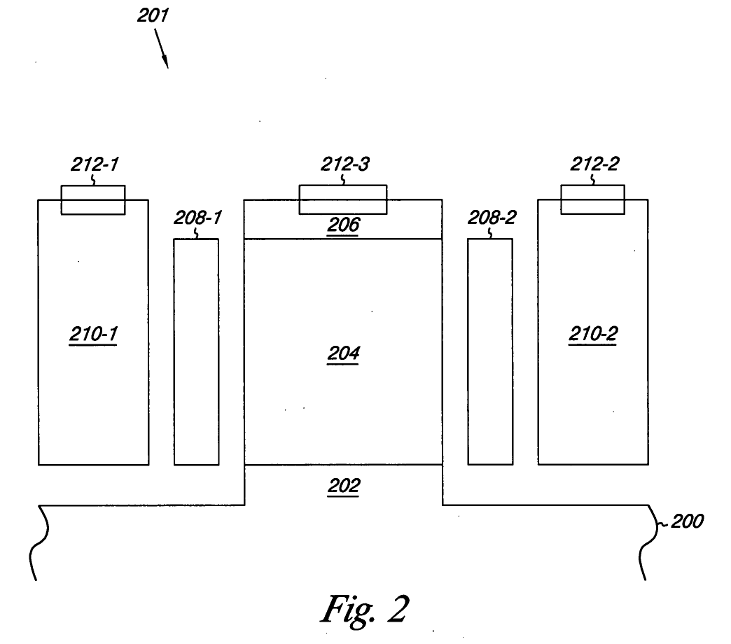

FIG. 2 illustrates an embodiment for the random logic utilization of a memory in logic element 201, e.g., cell, that can be programmed and operated as part of a programmable computing array. The structure of the cell described in FIG. 2 is analogous to the cell structural embodiment described in connection with FIGS. 1A-1C. That is, the memory in logic cell 201 includes a first and a second floating gate, 208-1 and 208-2, (first input, FGA and FGB) which are symmetrically formed on opposing sides of a narrow, e.g., less than 100 nm, vertical, semiconductor pillar. A first and a second control gate, 210-1 and 210-2, (second and third inputs, CGA and CGB) are formed opposing the first and the second floating gates, 208-1 and 208-2, respectively.

The narrow, vertical, semiconductor pillar can be formed upon a substrate 200 according to known semiconductor fabrication techniques and include any number of suitable number of semiconductor materials. The semiconductor pillar is doped so as to form a source region 202, a body region 204, and a drain region 206.

However, according to one or more embodiments, the semiconductor pillar is sufficiently lightly doped, e.g., has a doping concentration of approximately 5×10¹⁵/cm³, such that a first threshold voltage Vt1 on one side of the body region 204 depends on the charge or absence of charge stored on the second floating gate 208-2 on the opposite side of the body region and upon a control gate potential applied to the second control gate 210-2 as a third input. Similarly, a second threshold voltage Vt2 on the other side of the body region 204 depends on the charge or absence of charge stored on the first floating gate 208-1 on the opposite side of the body region 204 and upon a control gate potential applied to the first control gate 210-1 as a second input. In this manner, the voltage thresholds, Vt1 and Vt2, on opposing sides of the body region 204 are not independent as they would be for two separate transistors.

As shown in the example embodiment of FIG. 2, the second and third inputs can be provided to the first and the second control gates, 210-1 and 210-2 by way of a first and a second contact pad, 212-1 and 212-2 respectively, to a surface of the first and the second control gates, 210-1 and 210-2. The first and the second floating gates are charged and discharged together to serves as the first input. A third contact pad 212-3 is provided to a surface of the drain region 206 of the vertical pillar. One of ordinary skill in the manner in which the first and the second floating gates, 208-1 and 208-2, can be charged and discharged, e.g., programmed, together using Fowler Nordheim tunneling, hot electron injection, etc., by applying appropriate potential levels to the first, second, and third contacts, 212-1, 212-2, and 212-3. Hence, the memory in logic cell 201 embodiment illustrated in FIG. 2 is reconfigurable as a logic gate and can be programmed to perform either an OR or an AND logic function. That is, if both floating gates, 208-1 and 208-2 (FGA and FGB) are charged negative the combined memory in logic cell 201 can only be turned on if both control gates, 210-1 and 210-2, (CGA and CGB) are positive. If both floating gates, 208-1 and 208-2 (FGA and FGB) are uncharged, then either control gate, 210-1 and 210-2, (CGA and CGB) going positive can turn the combined memory in logic cell 201 on. When an output of the third contact pad is connected to an inverter the combination can perform either NOR, NAND, or NOT logic operations as described in more detail in connection with FIGS. 3A-3C.

FIG. 3A illustrates a programmable computing array 300 implementing embodiments of the memory in logic cells described in connection with FIGS. 1A-2. As shown in the embodiment of FIG. 3A the programmable computing array 300 includes a number of memory in logic cells, 301-1, 301-2, . . . , 301-T, arranged in a matrix of columns, CL-1, CL-2, . . . , CL-M, and rows, R-1, R-2, . . . , R-N. Each of the memory in logic cells, 301-1, 301-2, . . . , 301-T, in the programmable computing array 300 can include the structure and operation described in connection with FIGS. 1A-2 above. That is, the memory in logic cells, 301-1, 301-2, . . . , 301-T, include a first and a second floating gate, 308-1 and 308-2, (first input, FGA and FGB) which are symmetrically formed on opposing sides of a narrow, e.g., less than 100 nm, vertical, semiconductor pillar. A first and a second control gate, 310-1 and 310-2, (second and third inputs, CGA and CGB) are formed opposing the first and the second floating gates, 308-1 and 308-2, respectively.

The narrow, vertical, semiconductor pillar can be formed upon a substrate according to known semiconductor fabrication techniques and include any number of suitable number of semiconductor materials. The semiconductor pillar is doped so as to form a source region 302, a body region 304, and a drain region 306. In one embodiment, the source regions 302 and drain regions 306 include n-type doping and the body regions 304 include p-type doping so as to form n-channel transistor structures to the memory in logic cells, 301-1, 301-2, . . . , 301-T. As shown in the embodiment of FIG. 3A, a contact 312-3, e.g., third contact shown in FIG. 2, is connected to the drain region 306 for each of the semiconductor pillars. A conductive row line, e.g., 316-1, . . . , 316-N, along each row, R-1, . . . , R-N, is connected to contacts 312-3. As shown in the embodiment of FIG. 3A, each of the row lines, 316-1, . . . , 316-N, are connected to a p-type transistor, 320-1, . . . , 320-N, which are supplied with Vdd voltage potential in order to form an inverter output.

As explained above, each of the semiconductor pillars in the programmable computing array 300 are sufficiently lightly doped, e.g., have a doping concentration of approximately 10¹⁵/cm³, such that a first threshold voltage Vt1 on one side of the pillar depends on the charge or absence of charge stored on the second floating gate 308-2 on the opposite side of the pillar and upon a control gate potential applied to the second control gate 310-2 as a third input. Similarly, a second threshold voltage Vt2 on the other side of the pillar depends on the charge or absence of charge stored on the first floating gate 308-1 on the opposite side of the pillar and upon a control gate potential applied to the first control gate 310-1 as a second input. In this manner, the voltage thresholds, Vt1 and Vt2, on opposing sides of the pillars in the programmable computing array 300 are not independent as they would be for two separate transistors.

As illustrated further in connection with the truth tables of FIGS. 3B and 3C, the logic that each of the cells, 301-1, 301-2, . . . , 301-T, outputs is dependent on the charge on the floating gates, e.g., 308-1 and 308-2, as a first input, a potential applied to a first control gate, 310-1, as a second input, and a potential applied to a second gate, 310-2, as a third input. When the memory in logic cells, 301-1, 301-2, . . . , 301-T, in the programmable computing array 300 are coupled to the p-type transistors, 320-1, . . . , 320-N, the output will be inverted to the opposite logical value. Hence, the programmable computing array 300 can function with the p-type transistors, 320-1, . . . , 320-N, to perform NAND and/or NOR logic functions, depending on the state, charged or uncharged, of the floating gates, 308-1 and 308-2 (first inputs) for various potential (logic inputs) to the first and the second control gates, 310-1 and 310-2 (second and third logical inputs).

FIG. 3B illustrates a truth table for various first, second, and third logical inputs to the programmable computing array 300 shown in FIG. 3A. As shown in FIG. 3A, the first logical input is the pair of floating gates, 308-1 and 308-2 (FGA and FGB), to each of the memory in logic cells, 301-1, 301-2, . . . , 301-T, represented as either charged (−) or uncharged (0V) in columns 316. In a first portion of the truth table 321, the truth table illustrates the logic performed by the programmable computing array 300 when both first and the second floating gates, 308-1 and 308-2 (FGA and FGB), are charged (−). In a second portion of the truth table 322, the truth table illustrates the logic performed by the programmable computing array 300 when both first and the second floating gates, 308-1 and 308-2 (FGA and FGB), are uncharged (0V).

As shown in FIG. 3B, the second logical input is the potential applied to the first control gate, 310-1 (CGA), of the memory in logic cells, 301-1, 301-2, . . . , 301-T, represented as a logic “1” or logic “0” value (column 326) depending on a high or low potential applied to the first control gate, 310-1 (CGA), along a column, CL-1, CL-2, . . . , CL-M respectively, of memory in logic cells, 301-1, 301-2, . . . , 301-T. The third logical input is the potential applied to the second control gate, 310-2 (CGB), of the memory in logic cells, 301-1, 301-2, . . . , 301-T, represented as a logic “1” or logic “0” value (column 328) depending on a high or low potential applied to the second control gate, 310-2 (CGB), along a column, CL-1, CL-2, . . . , CL-M, of memory in logic cells, 301-1, 301-2, . . . , 301-T.

As shown in the first portion of the truth table 321, when both the first and the second floating gates, 308-1 and 308-2 (FGA and FGB) are charged negative (−), the memory in logic cells, 301-1, 301-2, . . . , 301-T, function as a first logical gate type to perform a first logical operation based on the second and the third logical inputs. That is, the memory in logic cells, 301-1, 301-2, . . . , 301-T, function as “AND” logic gates such that only when a logical “1” value is applied to both the second logical input, e.g., the first control gate 310-1 (CGA), and to the third logical input, e.g., the second control gate 310-2 (CGB), will an output, as reflected in column 330, be a logical “1” value.

As shown in the second portion of the truth table 322, when both the first and the second floating gates, 308-1 and 308-2 (FGA and FGB) are uncharged (0V), the memory in logic cells, 301-1, 301-2, . . . , 301-T, function as a second logical gate type to perform a second logical operation based on the second and the third logical inputs. That is, the memory in logic cells, 301-1, 301-2, . . . , 301-T, function as “OR” logic gates such that when a logical “1” value is applied to either the second logical input, e.g., the first control gate 310-1 (CGA), or to the third logical input, e.g., the second control gate 310-2 (CGB), an output, as reflected in column 330, be a logical “1” value.

FIG. 3C illustrates a truth table for various first, second, and third logical inputs to the programmable computing array 300 shown in FIG. 3A when the memory in logic cells, 301-1, 301-2, . . . , 301-T, are additionally coupled to the p-type transistors, 320-1, . . . , 320-N, to invert the logical value output from the array. In this embodiment, the programmable computing array 300 functions with the p-type transistors, 320-1, . . . , 320-N, to perform NAND and/or NOR logic functions, depending on the state, charged or uncharged, of the floating gates, 308-1 and 308-2 (first inputs) for various potential (logic inputs) to the first and the second control gates, 310-1 and 310-2 (second and third logical inputs).

Again, the first logical input is the pair of floating gates, 308-1 and 308-2 (FGA and FGB), to each of the memory in logic cells, 301-1, 301-2, . . . , 301-T, represented as either charged (−) or uncharged (0V) in columns 334. In a first portion of the truth table 331, the truth table illustrates the logic performed by inverting the output of the programmable computing array 300 when both first and the second floating gates, 308-1 and 308-2 (FGA and FGB), are charged (−). In a second portion of the truth table 332, the truth table illustrates the logic performed by inverting output of the programmable computing array 300 when both first and the second floating gates, 308-1 and 308-2 (FGA and FGB), are uncharged (0V).

As shown in FIG. 3C, the second logical input is the potential applied to the first control gate, 310-1 (CGA), of the memory in logic cells, 301-1, 301-2, . . . , 301-T, represented as a logic “1” or logic “0” value (column 336) depending on a high or low potential applied to the first control gate, 310-1 (CGA), along a column, CL-1, CL-2, . . . , CL-M respectively, of memory in logic cells, 301-1, 301-2, . . . , 301-T. The third logical input is the potential applied to the second control gate, 310-2 (CGB), of the memory in logic cells, 301-1, 301-2, . . . , 301-T, represented as a logic “1” or logic “0” value (column 338) depending on a high or low potential applied to the second control gate, 310-2 (CGB), along a column, CL-1, CL-2, . . . , CL-M, of memory in logic cells, 301-1, 301-2, . . . , 301-T.

As shown in the first portion of the truth table 331, when both the first and the second floating gates, 308-1 and 308-2 (FGA and FGB) are charged negative (−), and the output of the memory in logic cells, 301-1, 301-2, . . . , 301-T, is inverted, the system functions as a third logical gate type to perform a third logical operation based on the second and the third logical inputs (CGA and CGB). That is, the inverted output of the memory in logic cells, 301-1, 301-2, . . . , 301-T, function to perform a “NAND” logic operation such that only when a logical “1” value is applied to both the second logical input, e.g., the first control gate 310-1 (CGA), and to the third logical input, e.g., the second control gate 310-2 (CGB), will an output, as reflected in column 340, be a logical “0” value.

As shown in the second portion of the truth table 332, when both the first and the second floating gates, 308-1 and 308-2 (FGA and FGB) are uncharged (0V), and the output of the memory in logic cells, 301-1, 301-2, . . . , 301-T, is inverted, the system functions as a fourth logical gate type to perform a fourth logical operation based on the second and the third logical inputs (CGA and CGB). That is, the inverted output of the memory in logic cells, 301-1, 301-2, . . . , 301-T, function to perform a “NOR” logic function such that when a logical “1” value is applied to either the second logical input, e.g., the first control gate 310-1 (CGA), or to the third logical input, e.g., the second control gate 310-2 (CGB), an output, as reflected in column 340, be a logical “0” value. Here, only when a logical “0” value is applied to both the second logical input, e.g., the first control gate 310-1 (CGA), and to the third logical input, e.g., the second control gate 310-2 (CGB), will an output, as reflected in column 340, be a logical “1” value.

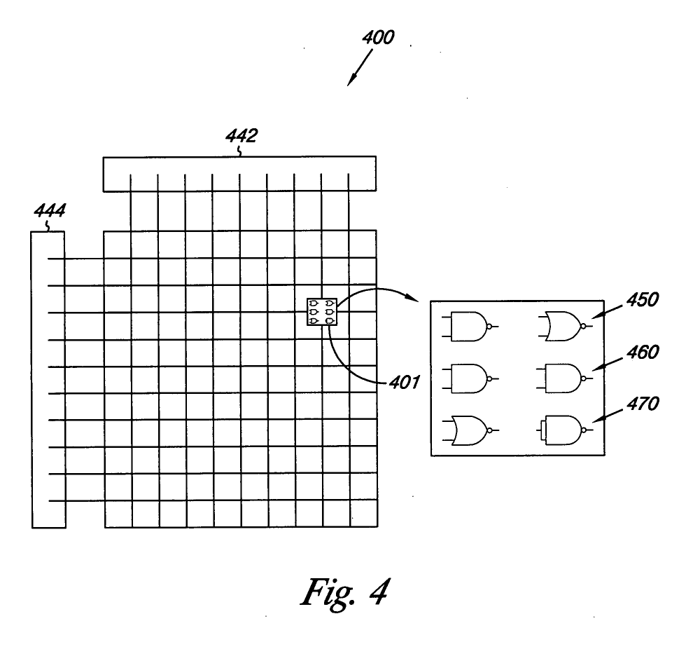

FIG. 4 illustrates a programmable computing array 400 implementing embodiments of the memory in logic cells described in connection with FIGS. 1A-3C. As shown in the embodiment of FIG. 4, the programmable computing array 400 includes a number of memory in logic cells, e.g., 401, arranged in an array of columns and rows, e.g., having control gate lines 410 coupled to a column address decoder 442 and having row lines 416 coupled to a row address decoder 444 and to the third contact (312-3 in FIG. 3) of each of the cells 401. Each of the memory in logic cells, e.g., 401, in the programmable computing array 400 can include the structure and operation described in connection with FIGS. 1A-3C above, e.g., can be programmed to perform a NOR 450, a NAND 460, a NOT logical operation, etc.

As explained above, the logic function of a given cell 401 the array 400 is dependent on the charge on the floating gates, e.g., first inputs, and the potential applied to the control gates, e.g., second and third inputs, associated with the given cell 401. A memory in logic cell 401 in the array 400 performs a NAND logic function when the floating gates of a cell 401 are charged negative and the output of the cell 401 is inverted, as described in connection with FIGS. 3A-3C. A memory in logic cell 401 in the array 400 performs a NOR logic function when the floating gates are uncharged and the output of the cell 401 is inverted, as described in connection with FIGS. 3A-3C. A memory in logic cell 401 in the array performs a NOT logic function when only one of the control gates is used, e.g., using the second or third input only, and the floating gates are charged. Here, a logical “1” input on either the second or third inputs will output a logical “0”. If a logical “0” is input on either the second or third inputs and the output is inverted a logical “1” will result.

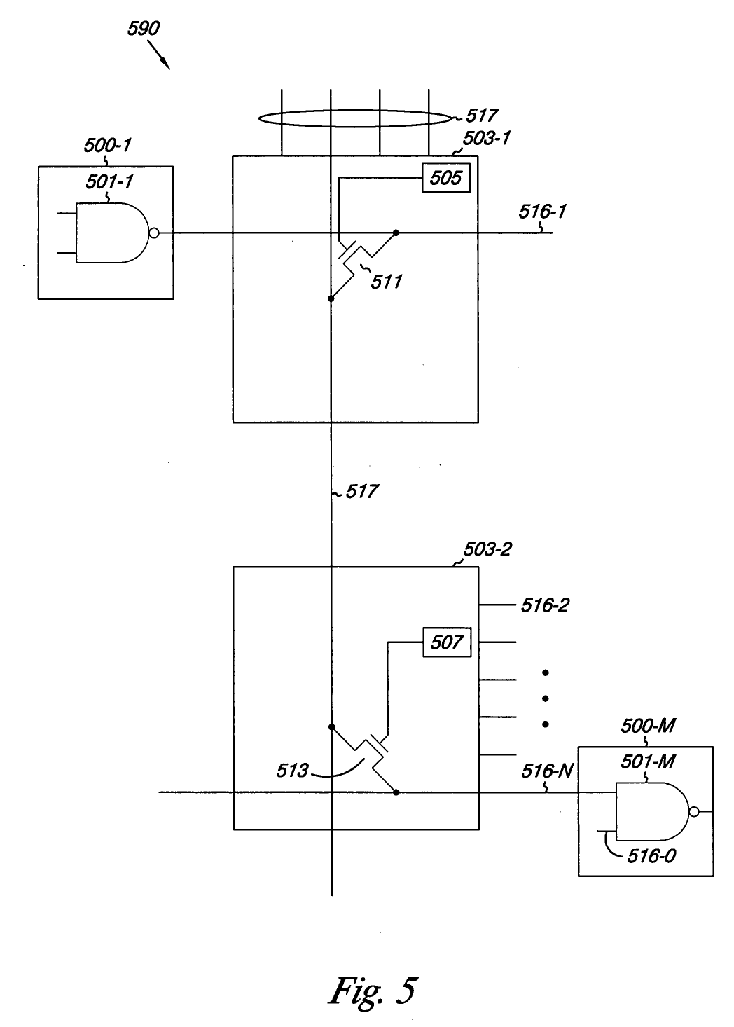

FIG. 5 illustrates an embodiment of a memory-in-logic computing system where multiple programmable computing arrays, e.g., 500-1, . . . , 500-M, are coupled together via a programmable routing structure, e.g., 503-1 and 503-2. The programmable computing arrays 500-1, . . . , 500-M implement embodiments of the memory in logic cells having the structure and operation described in connection with FIGS. 1A-4. That is, the floating gates, first inputs, and control gates, second and third inputs, to the memory in logic cells of the arrays, 500-1, . . . , 500-M, are configurable to allow the memory in logic cells to serve as NAND, NOR, or NOT logic gates, etc.

As shown in the embodiment of FIG. 5, the programmable computing arrays, 500-1, . . . , 500-M, can be connected through programmable routing structures 503-1, 503-2, etc. The programmable routing structures 503-1, 503-2, etc., can receive an output on row lines, e.g., 516-1, from a first programmable computing array, e.g., 500-1, and connect this signal on to other programmable computing arrays, effectively linking different logic blocks together to allow the logic functions to be combined. As shown in the embodiment of FIG. 5, the programmable routing structures 503-1, 503-2 can include a matrix of pass transistors, e.g., two pass transistors 511, 513, etc., and may themselves include programmable memory in logic cells, e.g., 505 and 507 as the same have been described herein, to control the gates of such pass transistors, e.g., 511, 513, etc.

Hence, the programmable routing structures 503-1, 503-2, etc., can be programmed using programmable logic devices 505, 507, such as the memory in logic cells described herein, to combine the logic signals from the memory in logic cells in the programmable computing arrays 500-1, . . . , 500-M, in a variety of ways. As shown in the embodiment of FIG. 5, a logic signal from a memory in logic cell in array 500-1 can be allowed to pass through the programmable routing structure 503-1 by addressing pass transistor 511 with address lines 517 and with the programmable logic device 505 to output a logical signal on line 516-1. Likewise address signals 517 can address pass transistor 513 together with the programmable logic device 507 to output a logical signal on line 516-N as an input to programmable computing array 500-M.

In this manner, an output of a first memory in logic cell, e.g., 501-1, in array 500-1, can be programmably connected as a first input, via line 516-N, to a second memory in logic cell, e.g., 501-M in array 500-M, via one or more programmable routing circuits, e.g., 503-1, 503-2, etc. Moreover, output of a third memory in logic cell can be connected as a second input, e.g., 516-0, to the second memory in logic cell, e.g., 500-M. As the reader will appreciate the second memory in logic cell, 500-M, can be configured to perform a third logical operation. Although the example embodiment of FIG. 5 illustrates an output from a first programmable computing array 500-1 as an output from a memory in logic cell 501-1 configured to perform a NAND logic function, and the input to a programmable computing array 500-M as being input to a memory in logic cell 500-M similarly configured to perform a NAND logic function, embodiments are not limited to this example.

As one of skill in the art will appreciate upon reading this disclosure, embodiments include an output from a first programmable array, having cells configured to perform the first logical operation, being provided as an input to a second programmable array, having cells configured to perform as second, different logical operation. Additionally, a first output from a first programmable array can be provided as an input to a second programmable array and a second output from the first programmable array can be provided as an input to a third programmable array via the programmable routing structures, 503-1, 503-2, etc., described herein.

### CONCLUSION

Methods, devices, and systems for programmable computing arrays have been described. One or more embodiments include programming both a first and a second floating gate of a combined memory and logic element to one of at least two states, wherein programming the floating gates to one of the at least two states causes the combined memory and logic element to operate as a first logic gate type. One or more embodiments also include programming both the first and the second floating gates of the combined memory and logic element to another of the at least two states, wherein programming the floating gates to another of the at least two states causes the combined memory and logic element to operate as a second logic gate type, the second logic gate type being different from the first logic gate type.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A method for operating a programmable computing array, comprising:
programming both a first and a second floating gate of a combined memory and logic element to one of at least two states, wherein programming the floating gates to one of the at least two states causes the combined memory and logic element to operate as a first logic gate type; and
programming both the first and the second floating gates of the combined memory and logic element to another of the at least two states, wherein programming the floating gates to another of the at least two states causes the combined memory and logic element to operate as a second logic gate type, the second logic gate type being different from the first logic gate type.

2. The method of claim 1, wherein the method includes using a first control gate associated with the first floating gate as a first logical input and using a second control gate associated with the second floating gate as a second logical input.

3. The method of claim 2, wherein the method includes using the first and the second floating gates as a third logical input.

4. The method of claim 3, wherein programming the combined memory and logic element to the first state causes the combined memory and logic element to operate as a AND gate.

5. The method of claim 4, wherein programming the combined memory and logic element to the first state includes charging the first and the second floating gates negative.

6. The method of claim 5, wherein the method includes inverting an output of the combined memory and logic element to perform a NAND logic function.

7. The method of claim 3, wherein programming the combined memory and logic element to the second state causes the combined memory and logic element to operate as an OR gate.

8. The method of claim 7, wherein programming the combined memory and logic element to the second state includes removing a charge from both the first and the second floating gates.

9. The method of claim 8, wherein the method includes inverting an output of the combined memory and logic element to perform a NOR logic function.

10. The method of claim 1, wherein the method includes using a first control gate associated with the first floating gate as a first logical input.

11. The method of claim 10, wherein the method includes using the first and the second floating gates as a third logical input.

12. The method of claim 11, wherein programming the combined memory and logic element to the first state and inverting an output of the combined memory and logic element causes the combined memory and logic element to operate as a NOT gate.

13. A method operating a programmable computing array, comprising:
providing a first input to a first control gate of a combined memory and logic element;
providing a second input to a second control gate of the combined memory and logic element; and
providing a third input to a first and a second floating gate of the combined memory and logic element.

14. The method of claim 13, wherein the method includes providing the first, the second, and the third inputs to a vertical dual floating gate transistor.

15. The method of claim 14, wherein the method includes providing the first, the second, and the third inputs to a symmetrical dual floating gate transistor.

16. The method of claim 13, wherein the method includes charging the first and the second floating gates to a same charge state.

17. The method of claim 13, wherein the method includes inverting an output of the combined memory and logic element.

18. The method of claim 17, wherein providing the third input includes providing a negative charge to the first and the second floating gates.

19. The method of claim 18, wherein providing the first and the second input to the combined memory and logic element performs a NAND operation.

20. The method of claim 18, wherein providing the first input to the combined memory and logic element performs a NOT operation.

21. The method of claim 17, wherein providing the third input includes removing a charge from the first and the second floating gates.

22. The method of claim 21, wherein providing the first and the second input to the combined memory and logic element performs a NOR operation.

23. The method of claim 21, wherein providing the first input to the combined memory and logic element performs a NOT operation.

24. The method of claim 13, wherein the method includes providing an output of a first combined memory and logic element as an input to a second combined memory and logic element.

25. The method of claim 24, wherein the method includes providing the input to the second combined memory and logic element having a first and a second floating gate programmed to a different charge state from a charge state of a first and a second floating gate of the first combined memory and logic element.

26. The method of claim 25, wherein method includes:
providing the output from a first combined memory and logic element that is programmed as AND gate;
inverting the output; and
providing the inverted output to a second combined memory and logic element that is programmed as an OR gate.

27. The method of claim 13, wherein the method includes:
providing an output of a first combined memory and logic element as the first input to a second combined memory and logic element; and
providing an output of a third combined memory and logic element as a second input to the second combined memory and logic element.

28. A programmable, combined memory and logic element, comprising:
a first and a second floating gate providing a first logical input to the element;
a first control gate providing a second logical input to the element; and
a second control gate providing a third logical input to the element.

29. The combined memory and logic element of claim 28, wherein the first and the second floating gates are formed vertically and symmetrically oppose a vertical body region having a width and a doping concentration such that a charge on the first floating gate on one side of the body region and a control gate potential applied to the first control gate control a threshold voltage for the other side of the body region opposing second floating gate.

30. The combined memory and logic element of claim 29, wherein the vertical body region is less than 100 nanometers in width.

31. The combined memory and logic element of claim 29, wherein the vertical body region has a doping concentration of less than 10¹⁷/cm³.

32. The combined memory and logic element of claim 28, wherein the element is configured to:
perform a first logical operation when the first and the second floating gates are in a first state; and
perform a second logical operation when the first and the second floating gates are in a second state.

33. The combined memory and logic element of claim 28, wherein the first and the second floating gates are programmed together.

34. The combined memory and logic element of claim 28, wherein the element is configured to:
operate as an AND gate when the first and second floating gates are programmed to a first state; and
operate as an OR gate when the first and second floating gates are programmed to a second state.

35. A memory in logic computing system, comprising:
a programmable array having a number of memory in logic elements formed at the intersections of a first and second set of address lines, wherein the memory in logic elements include:
a first and a second floating gate providing a first logical input to the element;
a first control gate providing a second logical input to the element;
a second control gate providing a third logical input to the element; and
wherein the elements each perform a first logical operation when the first and the second floating gates are in a first state and each perform a second logical operation when the first and the second floating gates are in a second state.

36. The system of claim 35, wherein the memory in logic elements have vertical floating gates.

37. The system of claim 35, wherein the output of a first memory in logic element is connected as a first input to a second memory in logic element via a programmable routing circuit.

38. The system of claim 37, wherein the output of a third memory in logic element is connected as a second input to the second memory in logic element.

39. The system of claim 38, wherein the second memory in logic element is configured to perform a third logical operation.

40. The system of claim 35, wherein an output from a first programmable array, having elements configured to perform the first logical operation, is provided as an input to a second programmable array, having elements configured to perform as second logical operation.

41. The system of claim 35, wherein a first output from a first programmable array is provided as an input to a second programmable array and a second output from the first programmable array is provided as an input to a third programmable array.

42. The system of claim 35, wherein an inverter is connected to at least one of the address lines to invert an output of an addressed element.
